(19) United States
(12) Patent Application Publication
(10) Pub. No.: US 2006/0012055 A1
(43) Pub. Date: Jan. 19, 2006

(54) Semiconductor package including rivet for bonding of lead posts

(76) Inventors: Chee Seng Foong, Selangor (MY); Bee Hoon Liau, Singapore (SG); Wai Yew Lo, Selangor (MY); Hua Wai Ong, Melaka (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/891,735

(22) Filed: Jul. 15, 2004

(51) Int. Cl. H01L 23/48

(52) U.S. Cl. 257/780

(57) ABSTRACT

A semiconductor device (30,30′) includes a semiconductor die (32, 32′) having bonding pads (34, 34′) and ball bumps (38, 38′). Each of the ball bumps (38, 38′) has a base portion (40, 40′) and a protruding portion (42, 42′). The semiconductor die (32, 32′) is mounted on a lead frame having lead posts (44, 44′) such that each of the lead posts (44, 44′) is aligned to a respective one of the ball bumps (38, 38′). Each of the lead posts (44, 44′) has an opening (46, 46′) that extends from a first surface of the lead post (44, 44′) through to a second surface of the lead post (44, 44′). The opening (46, 46′) contains the protruding portion (42, 42′) of the respective one of the bumps (38, 38′) to facilitate alignment and bonding. A rivet (50, 50′) is formed from the protruding portion (42, 42′) of the respective one of the plurality of bumps (38, 38′) on the surface of the lead posts (44, 44′), which provides for bonding and securing of the lead posts (44, 44′) to the semiconductor die (32, 32′).

### BACKGROUND OF THE INVENTION

The present invention relates to semiconductor devices in general and more specifically to a semiconductor package including an attached lead frame and method for making the same.

Semiconductor manufacturers are constantly striving to make the overall size of semiconductor devices smaller. Recent advances in semiconductor packaging to accommodate this necessity of minimizing the overall package size, indicate a migration from wire bond, where the chip or die is interconnected to the package only on the periphery of the die, to tape automated bonding (TAB), where leads are bonded to a set of bonding pads formed on a semiconductor die, and flip-chip soldering, where the die is interconnected to the package using the entire die area.

One attempt to reduce overall package size is through the use of TAB leads, or posts, formed from a very thin conductor that is laminated to a film carrier rather than from a stamped or etched metal frame. TAB leads can be made much smaller, resulting in smaller semiconductor devices. In a semiconductor device, TAB leads are bonded to a set of bonding pads formed on a semiconductor die through an intermediate means, such as bumps, pads, or balls, in order to provide electrical connection to various circuits on the die. TAB assembly is generally limited to interconnection of perimeter I/O arrays, thus limiting the IC design flexibility.

Flip-chip bonding is another process used to reduce overall chip size. In one type of flip-chip assembly, a semiconductor die is attached to a standard lead frame by means of solder, in the form of bumps, pads, or balls, commonly referred to as “C4” bumps. Conventional controlled collapse chip collect (C4) bumps are uniform circular bumps for standard lead frame or TAB lead attachment, typically formed of gold by either electroplating or by forming ball bumps from a standing wire bonding tool. In the bump electroplating process, a surface of the die having the bonding pads located thereon is initially coated with a thin layer of sputter deposited gold. A mask is formed on the thin gold layer and patterned to expose the sputtered gold layer overlying the bonding pads of the die. Exposed portions of the sputtered gold layer are then plated with gold, usually by electrodeposition, to increase the gold thickness over the bonding pad area, thereby forming a plurality of gold bumps on the die surface. After forming the bumps, the mask is removed and a chemical etch is used to remove the sputter deposited gold layer on the non-bumped portions of the die surface.

In the ball bumping process a conventional wire bonding tool is used to form bumps on bonding pads of a semiconductor die. A fine gold wire is bonded to the bonding pad and then cut or severed. In bonding the wire to the bonding pad, the wire is compressed into a ball shape. As illustrated in FIG. 1, a semiconductor device 10 has a plurality of ball bumps 12, formed from a fine gold wire, bonded to respective ones of a plurality of bonding pads 14 located on a die surface 16. The ball bumps 12 are bonded to the bonding pads 14 by compressing the wire against the bonding pads 14 and then severing the wire to form the bump 12. Upon bonding the wire, a rounded base portion 18 of the bump is formed as a result of compressing the wire against the die surface 16. A tail portion 20 above the base portion 18 is formed as the wire is drawn away from the die surface 16 during the bonding procedure. At a predetermined distance from the die surface 16, the wire is broken to complete the bump 12. To suitably bond lead posts to the bonding pads 14, as illustrated in FIG. 2, the tail portions 20 of the bumps 12 must be removed or flattened before the lead is bonded to it. In other instances, the tail portion 20 is permitted to protrude into an opening formed in the lead. In FIG. 2, the semiconductor device 10 of FIG. 1 is shown in which a plurality of lead posts 22 are bump bonded to the bonding pads 14 using conventional bumps 12.

Hereinafter, all conductive bump connection techniques, both formed by electroplating or ball bumping will be referred to collectively as “micro-bump bonding”. Irrespective of the type of micro-bump bonding used, and whether formed by solder bumps or through electroplating fabrication, there is a problem with delamination and thus the interfacial adhesion strength between the bump bonds and the lead posts, being either standard lead posts or TAB posts, of the lead frame. It is difficult to ensure that the ball bumps formed on the semiconductor die bonding pads will successfully fuse to the lead frame lead posts and the resultant mechanical strength of the fusion.

Therefore, a need exists for an improved semiconductor device, and more specifically for a semiconductor device having one of standard lead posts or TAB lead posts and a method for making the same that provides for increased adhesion strength between the bump bonds and the lead posts during the micro bump bonding process.

Accordingly, it is an object of the present invention to provide a semiconductor package including increased bond strength between the lead posts of the lead frame and the semiconductor die.

It is another object of the present invention to provide a robust semiconductor package having increased mechanical bond strength in flip chip semiconductor package fabrication.

It is yet another object of the present invention to provide a robust semiconductor package having increased mechanical bond strength in TAB lead semiconductor package fabrication.

It is still another object of the present invention to provide a method of fabricating a semiconductor package including increased bond strength between the lead posts of the lead frame and the semiconductor die.

### BRIEF DESCRIPTION OF THE DRAWINGS

The following detailed description of a preferred embodiment of the invention will be better understood when read in conjunction with the appended drawings. The present invention is illustrated by way of example and not limited by the accompanying figures, in which like references indicate similar elements.

FIG. 1 is a perspective view of a conventional semiconductor device illustrating ball bumps having a tail portion;

FIG. 2 is a perspective view of a portion of the conventional semiconductor device of FIG. 1 illustrating bonding of lead posts of a lead frame to bonding pads using ball bumps;

FIGS. 3-5 are cross-sectional views illustrating the steps in the process of bonding lead posts to a semiconductor device in accordance with a first embodiment of the present invention;

FIGS. 6-7 are cross-sectional views illustrating the steps in the process of bonding lead posts to a semiconductor device in accordance with a second embodiment of the present invention;

FIG. 8 is a perspective view of a lead post that represents the lead being bonded to a semiconductor device in accordance with the second embodiment of the present invention; and

FIGS. 9-12 are top plan views of lead posts illustrating openings formed in the lead posts according to the present invention.

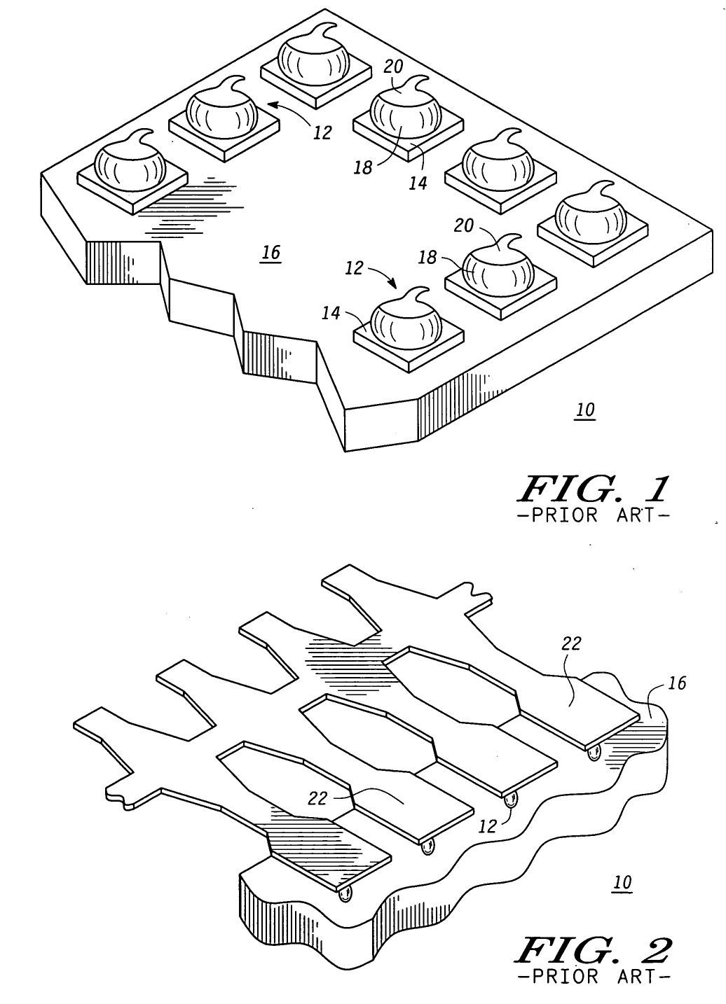

### DETAILED DESCRIPTION OF THE PREFERRED EMBODIMENTS

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

To achieve the objects and advantages discussed above and others, the present invention is a semiconductor device having lead posts that facilitate lead bonding. The device comprises a semiconductor die having a plurality of bonding pads and a plurality of bumps, each bump being formed on a respective one of the plurality of bonding pads. The device also has a plurality of lead posts, each lead posts being bonded to a respective one of the plurality of bumps and having an opening formed therethrough which accommodates a portion of the respective one of the plurality of bumps in order to facilitate lead bonding. The device further includes a rivet formed by coining the portions of the bumps that protrude through the lead posts openings and thereby riveting the lead posts with the bumps, or by heating the bumps to reflow solder through the openings, thereby wetting the lead posts, such that upon cooling provides for riveting of the lead posts.

Typically C4 bumps on lead frame packages have relatively low adhesion strength between the two contacting surfaces and are therefore prone to delamination. The adhesion strength between a semiconductor die and lead frame directly affects the reliability of the device. Accordingly, by providing for a better bond, the interfacial adhesion strength between C4 bumps and lead posts of the lead frames is increased. The present invention provides for increased strength between the C4 bumps and the lead posts of the lead frame by providing a means for securely fastening the lead posts to the semiconductor die. The invention will most commonly be employed in devices in which bump bonds are used, but may also be implemented in devices that use plated bumps.

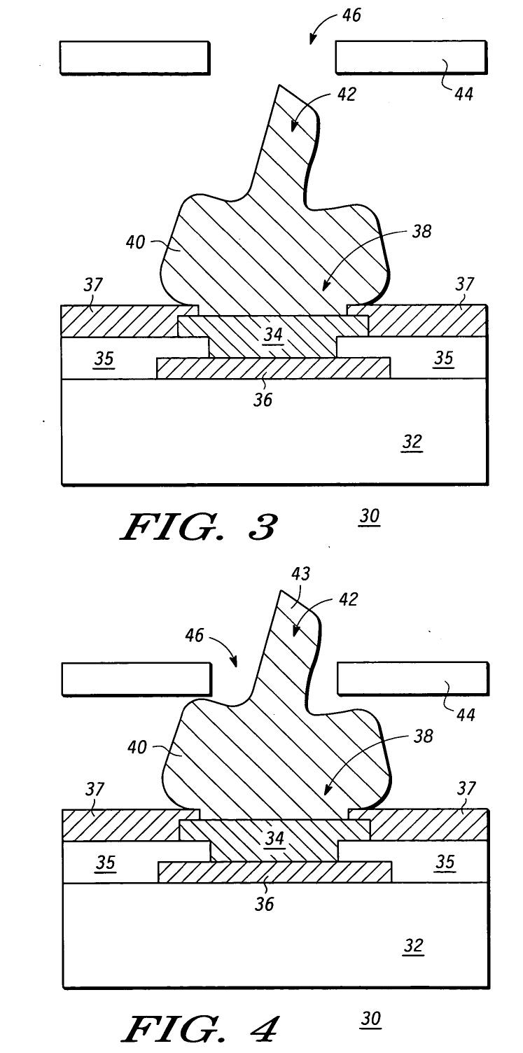

Illustrated in cross-sectional view in FIGS. 3-5 are steps in the process of bonding a lead post to a semiconductor device in accordance with a first embodiment of the present invention. Referring more specifically to FIG. 3, illustrated is a semiconductor device 30 including a semiconductor die 32 having a bonding pad 34 located on the die surface. The semiconductor die 32 may be an integrated circuit, for example a memory device, a microprocessor, an analog device, a gate array, or the like. A material that is commonly used as a bulk die material is silicon, although other materials are also suitable. The bonding pad 34 in this particular example is formed on an uppermost surface of a copper trace 36. It should be understood that although only a single bonding pad 34 is illustrated, a plurality of bonding pads are typically formed as a part of the semiconductor device 30. The bonding pad 34 is formed of a conductive material, for example aluminum or an aluminum alloy that is deposited on an uppermost surface of the copper trace 36. The semiconductor device 30 also includes a passivation layer 35 and a layer of polyimide 37 formed about the bonding pad 34. A ball bump 38 is formed on the bonding pad 34. The ball bump 38 is typically made of gold or a gold alloy. As described earlier in the background section, the ball bump 38 is formed on the bonding pad 34 by compressively bonding a fine gold or gold alloy wire to the pad 34 and breaking the wire at a predetermined distance away from the bond. The ball bump 38 includes a base portion 40 and a tail portion 42. In many conventional devices, the tail portion 42 has to be flattened or coined prior to lead bonding. However, in the present invention the coining of tail portion 42 prior to the bonding of the lead is not performed. To accomplish this a lead post 44 that accommodates the shape of the ball bump 38 is used. As illustrated, the lead post 44 is formed having an opening 46 therethrough. The lead post 44 preferably includes gold plating around the opening 46. The positioning of the lead post 44 and the opening 46 defined therethrough relative to the tail portion 42 of the ball bump 38 is illustrated.

Referring now to FIG. 4, illustrated is a cross-sectional view of a second step in the process of bonding the lead post 44 to the bonding pad 34 by way of the ball bump 38 in accordance with a first embodiment of the present invention. The lead post 44 is lowered and thus positioned such that the tail portion 42 of the ball bump 38 protrudes through the opening 46 defined in the lead post 44. This protrusion 43 of the tail portion 42 through the hole 46 provides for improved alignment of the lead post 44 relative to the bonding pad 34, in addition to providing for a means for securing the lead post 44 to the ball bump 38, and more particularly to the bonding pad 34.

The lead post 44 in this particular example is illustrated as being a conventional lead frame lead having the opening 46 defined therethrough, but it should be understood that anticipated by this disclosure is the use of TAB leads having a similar opening defined therethrough. TAB leads are typically formed as a composite of various conductive and insulating layers that are laminated together. It should additionally be understood that the lead bonding in this disclosure is accomplished using any of the known bonding techniques including, but not limited to, thermosonic, thermo-compression, ultrasonic, laser, or reflow bonding techniques (as described herein).

The base portion 40 of the bump 38 is adjoined to the tail portion 42 and is adjacent the bonding pad 34. Since the opening 46 is used to facilitate bonding, it is formed near the lead tip. The opening 46 may be formed anywhere within the lead post that overlies the semiconductor die 32. The fabrication of a lead post having an opening formed therein is best described in U.S. Pat. No. 5,132,772, entitled “SEMICONDUCTOR DEVICE HAVING TAPE AUTOMATED BONDING LEADS WHICH FACILITATE LEAD BONDING”, and incorporated herein by this reference. It should be understood that in this particular invention, irrespective of the type of lead used, an opening is formed therethrough to facilitate bonding. When the lead post 44 is bonded to the bump 38, the combination of the opening 46 and the tail portion 42 guides the lead post 44 to a proper, centered location over the bump 38.

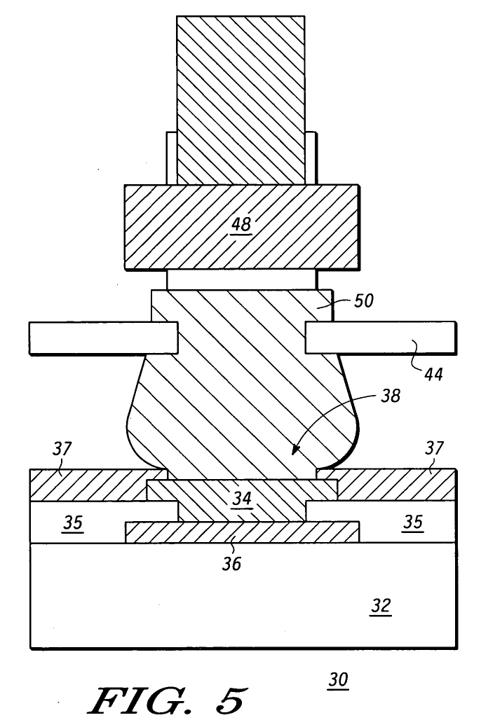

Referring now to FIG. 5, illustrated is a cross-sectional view of a final step in the process of bonding the lead post 44 to the bonding pad 34 by way of the ball bump 38 in accordance with the first embodiment of the present invention. A coining tool bit 48 is lowered and contacts the protruding portion 43 of the tail portion 42 of the ball bump 38. The coining tool 48 is pressed against the ball bump 38, which forms a rivet 50 from the protrusion 43 of the tail portion 42 by compression alone, or thermo-sonically. The rivet 50 locks the lead post 44 in place. This type of secure bonding increases the reliability of each bump connection. Accordingly, delamination or intermetallic crack issues are no longer of concern. In addition, the fabrication of the rivet 50 provides for a stronger connection of the bumps at the surface of the semiconductor die 32 and improved electrical connections.

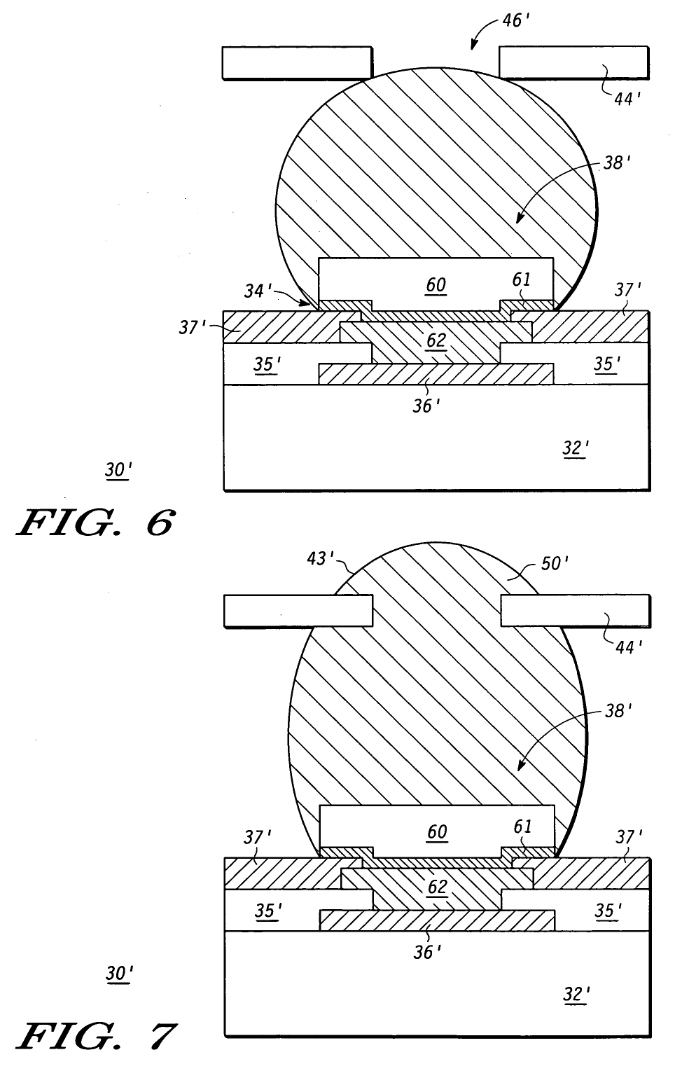

Referring now to FIGS. 6 and 7, illustrated are steps in the process of bonding a lead post to a semiconductor device in accordance with a second embodiment of the present invention. It should be noted that all components similar to the components of the first embodiment, as illustrated in FIGS. 3-5, are designated with similar numbers, having a prime added to indicate the different embodiment.

Referring now to FIG. 6, illustrated is a cross-sectional view of a first step in the process. A semiconductor device 30′ includes a semiconductor die 32′ having a bonding pad 34′ located on the die surface. The semiconductor die 32′ may be an integrated circuit, for example a memory device, a microprocessor, an analog device, a gate array, or the like. A material that is commonly used as a bulk die material is silicon, although other materials are also suitable. The semiconductor device 30′ also includes a passivation layer 35′ and a layer of polyimide 37′ formed about the bonding pad 34′. The bonding pad 34′ is formed of a conductive material, for example aluminum or an aluminum alloy cap 62 that is deposited on an uppermost surface of a copper trace 36′. In addition, in this particular example the bonding pad 34′ includes a copper stud 60 and a layer of titanium tungsten 61, formed on the cap 62. It should be understood that although only a single bonding pad 34′ is illustrated, a plurality of bonding pads are typically formed as a part of the semiconductor device 30′.

Formed on the bonding pad 34′ is a ball bump 38′, which is most often made of gold or a gold alloy. As described earlier, the ball bump 38′ is formed on the bonding pad 34′ by compressively bonding a fine gold or gold alloy wire to the pad 34′ and breaking the wire at a predetermined distance away from the pad 34′. Alternatively, the ball bump 38′ is formed by plating, as is known in the art. In this particular embodiment, the ball bump 38′ is flattened or coined prior to lead bonding, although this is not a required step. A lead post 44′ is formed having an opening 46′ formed therethrough. The lead post 44′ preferably has gold plating on at least a portion of the lead post 44′ that comes in contact with the ball bump 38′. The positioning of the lead post 44′ relative to an uppermost portion of the ball bump 38′ is shown. The opening 46′ provides for proper alignment of the lead post 44′ relative to the semiconductor die 32′.

Referring now to FIG. 7, illustrated is a cross-sectional view of a second step in the process of bonding the lead post 44′ to the ball bump 38′ in accordance with a second embodiment of the present invention. The lead post 44′ is lowered and pressed slightly onto the bump 38′, thereby slightly deforming the bump 38′. Thereafter, the device 30′ is heated in a reflow oven to melt the bump 38′ in order for the solder to wet the lead posts 44′. During the reflow process, a portion of the molten bump will flow up through the opening 46′, resulting in a protruding portion 43′. Upon cooling to room temperature, the bump 38′, including the protruding portion 43′, solidifies forming half domes on both sides of the lead post 44′, thereby bonding the lead post 44′, and forming a self-forming rivet 50′. This fabrication of the rivet 50′ provides for locking the lead posts 44′ in place.

The lead post 44′ in this particular example is illustrated as being a conventional lead frame lead having the opening 46′ defined therethrough, as previously disclosed with respect to the first embodiment. It is to be understood that anticipated by this disclosure is the use of TAB leads having a similar opening defined therethrough.

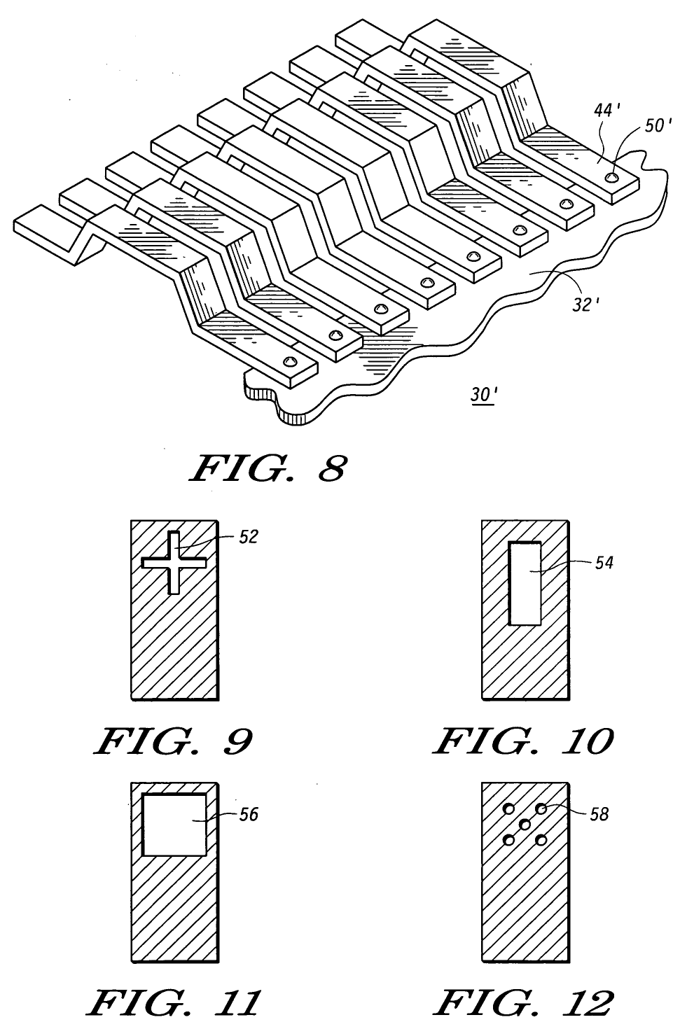

Referring now to FIG. 8, illustrated is the final device fabrication of the semiconductor package 30′, according to the second embodiment. As shown, half domes are formed on an uppermost surface of the lead posts 44′, thereby forming the rivets 50′ that securely lock the lead posts 44′ to the semiconductor die 32′. It should be noted that in both the first and second embodiments, the protruding portions 43 and 43′ fill all or substantially all of the holes 46 and 46′, respectively.

As disclosed, this invention comprises a typical flip chip die with C4 bumps, and a metal lead frame with plated thru hole lead posts. The C4 bumps can either be high temperature or low temperature bumps dependent upon application. The lead frame is disclosed as being either a conventional lead frames, such as a QFN or QFP type, or a lead frame having TAP leads formed. Unlike conventional lead frames, the lead posts as disclosed herein are required to have an opening formed therethrough to allow for the formation of the inventive rivet.

FIGS. 9-12 are top plan views of various embodiments of lead posts having openings therein. That is, the openings 46 and 46′ may take on various designs, as illustrated in FIGS. 9-12, for accommodating the tail portion 42 of the bump 38, or for aligning the bump 38′ prior to reheating. The disclosed shapes for the openings 46 and 46′ include a cross-shaped opening 52 as illustrated in FIG. 9, a rectangular opening 54 as illustrated in FIG. 10, a square opening 56 as illustrated in FIG. 11, or other regular or irregular geometric shapes. In addition, as illustrated in FIG. 12, multiple openings 58 formed in the lead posts 44 or 44′ are anticipated by this disclosure. While any shape opening in the lead posts is anticipated by this disclosure, there is a physical limitation to the size of the opening 46 and 46′ that is determined by the width and thickness of the lead post 44 and 44′.

As is evident from the foregoing discussion, the present invention provides for a semiconductor device having lead posts secured by rivets, and a method for making the same, which has benefits over existing devices and processes. As an example, the present invention increases the bond strength between the semiconductor die and the lead frame. In addition, the occurrence of delamination is greatly decreased due to the rivet formation. The riveting of the lead posts of the present invention is not available with either existing ball bumping or plated bumping techniques used to bonding conventional or TAB lead posts.

Thus it is apparent that there has been provided, in accordance with the invention, a semiconductor device having lead posts secured by rivets which facilitate lead bonding and a method for making the same that fully meets the advantages set forth previously. Although the invention has been described and illustrated with reference to specific embodiments thereof, it is not intended that the invention be limited to these illustrative embodiments. Those skilled in the art will recognize that modifications and variations can be made without departing from the spirit of the invention. For example, bump material is not limited to gold but may be any conductive material used in the art to form bumps for lead bonding. Likewise, the semiconductor device of the present invention is not limited to having one bump per semiconductor die bonding pad. As is commonly done in the industry, two or more bumps may be formed on an individual bonding pad. As addressed earlier, the present invention is not limited by the shape of a bump or lead. Nor is the device configuration limited to flip chip package design. It is also important to note that the present invention is not limited in any way to specific bump formation or bonding techniques. Any bumping techniques or lead bonding techniques known in the art may be used in accordance with the present invention. Furthermore, the present invention is not limited to those types of semiconductor die described or illustrated herein. Therefore, it is intended that this invention encompass all such variations and modifications as fall within the scope of the appended claims.

1. A semiconductor device comprising:
a semiconductor die having a plurality of bonding pads thereon;
a plurality of ball bumps, each bump having a base portion and a protruding portion, the base portion of each bump being formed on one of the plurality of bonding pads;
a lead frame, having a die pad and a plurality of lead posts surrounding the die pad, the semiconductor die being mounted on the lead frame so that each lead post is aligned to a respective one of the plurality of ball bumps, each of the plurality of lead posts having an opening that extends from a first surface of the lead posts through to a second surface of the lead posts, the second surface being opposite the first surface, wherein the opening contains the protruding portion of the respective one of the plurality of ball bumps in order to facilitate alignment and bonding of the lead posts and die pads; and
a rivet formed from the protruding portion of the respective one of the plurality of bumps on the second surface of the lead frame, thereby providing for bonding and securing of the lead frame to the semiconductor die.

2. The semiconductor device of claim 1, wherein the ball bumps are comprised of gold.

3. The semiconductor device of claim 1, wherein the protruding portion of the ball bump is formed as a tail on the base portion.

4. The semiconductor device of claim 1, wherein the protruding portion of the ball bump is formed when the ball bump is heated and reflowed through the opening in the lead posts.

5. The semiconductor device of claim 1, wherein the ball bump is formed from a conductive wire.

6. The semiconductor device of claim 1, wherein the ball bump is formed by electroplating.

7. The semiconductor device of claim 1, wherein the rivet is a coined rivet.

8. The semiconductor device of claim 1, wherein the rivet is a self-forming rivet.

9. The semiconductor device of claim 8, wherein the self-forming rivet is formed as a half dome on the second surface of the lead posts.

10. The semiconductor device of claim 1, wherein each lead post opening comprises a plurality of closely spaced openings.

11. The semiconductor device of claim 1, wherein each lead post opening is generally t-shaped.

12. A semiconductor device having a plurality of lead posts that facilitate lead bonding, comprising:
a semiconductor die having a plurality of bonding pads thereon;
a bump located on and electrically coupled to each of the plurality of bonding pads, the bump having a base portion that is adjacent the bonding pad and a protruding portion adjoining the base portion;
a plurality of lead posts electrically coupled to the plurality of bonding pads by way of the bumps, each lead post having an opening that contains at least the protruding portion of one of the bumps; and
a rivet formed from the protruding portion of each of the bumps, thereby providing for bonding and securing of the lead posts to the bonding pads.

13. The semiconductor device of claim 12, wherein the bumps are comprised of gold.

14. The semiconductor device of claim 13, wherein at least a portion of each of the lead posts is plated with gold.

15. The semiconductor device of claim 12, wherein the ball bump is formed from a conductive wire.

16. The semiconductor device of claim 12, wherein the ball bump is formed by electroplating.

17. The semiconductor device of claim 12, wherein the protruding portion of the ball bump is coined to form the rivet.

18. The semiconductor device of claim 12, wherein the protruding portion of the ball bump is formed when the ball bump is heated and reflowed through the opening in the lead posts and cooled to form the rivet.

19. The semiconductor device of claim 18, wherein the rivet is formed as a half dome on the second surface of the lead posts.

20. A method of fabricating a semiconductor device, comprising the steps of:
providing a semiconductor die having a plurality of bonding pads thereon;
forming a plurality of ball bumps, each bump having a base portion and a protruding portion, the base portion of each bump being formed on a respective one of the plurality of bonding pads;
mounting a lead frame having a plurality of lead posts, wherein each lead posts is aligned to a respective one of the plurality of bumps, each of the plurality of lead posts having an opening that extends from a first surface of the lead posts through to a second surface of the lead posts, the second surface being opposite the first surface, wherein the opening receives at least the protruding portion of the respective one of the plurality of bumps to facilitate alignment and bonding; and
forming a rivet from the protruding portion of the respective one of the plurality of bumps on the second surface of the lead frame, thereby providing for bonding and securing of the lead frame to the semiconductor die.

21. The method of fabricating a semiconductor device of claim 20, wherein the step of forming a plurality of ball bumps includes forming the ball bumps from a gold wire.

22. The method of fabricating a semiconductor device of claim 20, wherein the step of forming a plurality of ball bumps includes forming the ball bumps from electroplated gold.

23. The method of fabricating a semiconductor device of claim 20, wherein the step of forming a plurality of ball bumps includes forming the protruding portion as a tail on the base portion.

24. The method of fabricating a semiconductor device of claim 23, wherein the step of forming a rivet includes coining the tail portion of the ball bump.

25. The method of fabricating a semiconductor device of claim 20, wherein the step of forming a plurality of ball bumps includes heating the ball bumps to reflow the ball bumps through the openings in the lead posts.

26. The method of fabricating a semiconductor device of claim 25, wherein the step of forming a rivet includes cooling the portion of the ball bump that has been reflowed through the opening in the lead posts to form a half dome on the second surface of the lead posts.
